(19) United States
(12) Patent Application Publication
(10) Pub. No.: US 2019/0094639 A1
(43) Pub. Date: Mar. 28, 2019

(54) ARRAY SUBSTRATE, MANUFACTURING METHOD THEREOF AND DISPLAY DEVICE

(71) Applicants: BOE TECHNOLOGY GROUP CO., LTD., Beijing (CN); Fuzhou BOE Optoelectronics Technology Co., Ltd., Fujian (CN)

(72) Inventors: Yao LIU, Beijing (CN); Xi CHEN, Beijing (CN); Jiamin LIAO, Beijing (CN); Zongxiang LI, Beijing (CN)

(21) Appl. No.: 15/939,392

(22) Filed: Mar. 29, 2018

(30) Foreign Application Priority Data
Sep. 27, 2017 (CN) 201710890955.2

(51) Int. Cl. G02F 1/1362; G02F 1/1368; G02F 1/1333; H01L 27/12

(52) U.S. Cl. CPC G02F 1/136286; G02F 1/1368; G02F 2201/123; H01L 27/124; G02F 2201/121; G02F 1/133345

(57) ABSTRACT

The present disclosure provides an array substrate, a manufacturing method thereof, and a display device. The array substrate includes: a base substrate, a gate line and a data line intersecting with each other over the base substrate, and a thin film transistor; the thin film transistor including: a gate electrode, an active layer disposed on the side of the gate electrode away from the base substrate, and a source electrode and a drain electrode disposed on the side of the active layer away from the base substrate, wherein the gate electrode is a part of the gate line; the source electrode is a part of the data line, and at least partial area of the source electrode is located within an area where orthogonal projections of the data line and of the gate line on the base substrate overlap with each other.

### CROSS-REFERENCE TO RELATED APPLICATIONS

This application is based on and claims priority to Chinese Patent Application No. 201710890955.2, filed on Sep. 27, 2017, the entire contents thereof are incorporated herein by reference.

### TECHNICAL FIELD

The present disclosure relates to the field of display technology, and in particular, to an array substrate, a manufacturing method thereof, and a display device.

### BACKGROUND

In the array substrate, a gate line and a data line located at different layers intersect with each other, and the two overlap with each other. A parasitic capacitance is generated between the upper and lower metal layers in the overlapping area, resulting in crosstalk on the signals from the metal traces. As the display area of the display device increases, metal traces applied to the large-sized array substrate become longer. Crosstalk causes signal delays between the gate lines and the data lines, resulting in poor display such as Crosstalk and Flicker.

In addition, in the array substrate, the gate line is usually located below the data line. At the overlapping part of the data line and the gate line, there is a problem that the data line has to climb across the gate line. Therefore, it is necessary to ensure that the data line has a certain width. In order to avoid the Data Open problem of the data line, the area where the data line overlaps with the gate line has to be larger, making the above problem of signal delay even more serious.

### SUMMARY

The present disclosure provides an array substrate, a manufacturing method thereof, and a display device.

The present disclosure provides the following technical solutions.

In one aspect, an embodiment of the present disclosure provides an array substrate, including: a base substrate, a gate line and a data line intersecting with each other over the base substrate, and a thin film transistor; the thin film transistor including: a gate electrode, an active layer disposed on the side of the gate electrode away from the base substrate, and a source electrode and a drain electrode disposed on the side of the active layer away from the base substrate, wherein the gate electrode is a part of the gate line; the source electrode is a part of the data line, and at least partial area of the source electrode is located within an area where orthogonal projections of the data line and of the gate line on the base substrate overlap with each other.

Optionally, in the case where the source electrode is entirely located in an area where the orthogonal projections of the data line and the gate line on the base substrate overlap with each other, the orthogonal projection of the gate line on the base substrate completely covers the orthographic projection of the active layer on the base substrate; and in the case where a partial area of the source electrode is located in an area where the orthogonal projections of the data line and the gate line on the base substrate overlap with each other, the orthogonal projection of the gate line on the base substrate partly covers the orthographic projection of the active layer on the base substrate.

Optionally, the pattern of the source electrode is a loop shape and surrounds the drain electrode.

Preferably, the loop shape is a rectangular loop or a circular loop.

Preferably, the data line includes: a part serving as the source electrode and a part serving as a main part of the trace line connecting to the source electrode, and an axis of symmetry of the loop coincides with an axis of symmetry of the main part of the trace line in the extending direction.

Optionally, a pattern of the source electrode is a U shape or a quasi-U shape, and the opening direction of the U shape or the quasi-U shape is perpendicular to the extending direction of the data line; and at least partial area of the drain electrode is located in the opening area of the U shape or the quasi-U shape.

Optionally, the array substrate further includes: a passivation layer disposed on the gate line, the data line, and the thin film transistor, a pixel electrode disposed on the passivation layer; and the pixel electrode is electrically connected to the drain electrode through a via hole on the passivation layer.

Preferably, the array substrate further includes: a common electrode disposed between the pixel electrode and the base substrate, in opposite to the base substrate.

Preferably, the common electrode is disposed in the same layer as the gate line.

In another aspect, an embodiment of the present disclosure provides a display device including the above array substrate.

In yet another aspect, an embodiment of the present disclosure provides a manufacturing method for an array substrate, including: a step of sequentially forming a gate line, a gate insulating layer, an active layer, a data line, and a drain electrode over a base substrate; wherein a part of the gate line serves as a gate electrode, an active layer is formed over the gate electrode, and a drain electrode is formed over the active layer; a part of the data line serves as a source electrode, and at least partial area of the source electrode is located in an area where orthogonal projections of the data line and of the gate line on the base substrate overlap with each other; and the gate electrode, the active layer, the source electrode and the drain electrode constitute a thin film transistor.

Optionally, the step of forming the data line and the drain electrode includes: sequentially forming a metal layer and a photoresist layer over the base substrate formed with the gate line, the gate insulating layer and the active layer; forming a photoresist pattern by exposing and developing the photoresist layer with a mask, with the region of the metal layer covered by the photoresist pattern corresponding to patterns of the data line and the drain electrode to be formed; and etching the region of the metal layer exposing to the photoresist pattern, to form patterns of the data line and the drain electrode below the photoresist pattern; and removing the photoresist pattern to form the data line and the drain electrode.

Optionally, before the step of sequentially forming a gate line, a gate insulating layer, an active layer, a data line and a drain electrode on a base substrate, the manufacturing method further includes a step of forming a common electrode on the base substrate.

Optionally, after the step of sequentially forming a gate line, a gate insulating layer, an active layer, a data line and a drain electrode on a base substrate, the manufacturing method further includes: a step of forming a passivation layer with a via hole over the base substrate, to expose the drain electrode below through the via hole; and a step of forming a pixel electrode over the passivation layer, and electrically connecting the pixel electrode with the drain electrode through the via hole.

### BRIEF DESCRIPTION OF THE DRAWINGS

In order to more clearly explain the embodiments of the present disclosure or the technical solutions in the related art, the drawings used in the description of the embodiments or the related art will be briefly described below. Apparently, the drawings in the following description are only some embodiments of the present disclosure, for those skilled in the art, other drawings may also be obtained based on these drawings without any creative effort.

FIG. 1 is a first top view of an array substrate according to an embodiment of the present disclosure;

FIG. 2 is a cross sectional view taken along a line AA′ in FIG. 1;

FIG. 3 is a top view of an array substrate provided in the related art;

FIG. 4 is a cross sectional view taken along a line AA′ in FIG. 3;

FIG. 5 is a second top view of an array substrate according to an embodiment of the present disclosure;

FIG. 6 is a top view of a data line in an array substrate according to an embodiment of the present disclosure;

FIG. 7 is a third top view of an array substrate according to an embodiment of the present disclosure; and

FIG. 8 is a fourth top view of an array substrate according to an embodiment of the present disclosure.

### DETAILED DESCRIPTION

The following clearly and completely describes the technical solutions in the embodiments of the present disclosure with reference to the accompanying drawings in the embodiments of the present disclosure. Apparently, the described embodiments are merely some but not all of the embodiments of the present disclosure. All other embodiments obtained by a person of ordinary skill in the art based on the embodiments of the present disclosure without creative effort shall fall within the protection scope of the present disclosure.

It should be noted that, unless otherwise defined, all terms (including technical and scientific terms) used in the embodiments of the present disclosure have the same meaning as commonly understood by those skilled in the art to which the present disclosure belongs. It should also be understood that terms such as those defined in a typical dictionary should be construed as having a meaning that is consistent with their meaning in the context of the related art without being interpreted in an idealized or overly formal sense unless expressly defined as such herein.

For example, the terms “first”, “second” and the like, as used in the description and claims of the present patent application, do not denote any order, quantity, or importance, but are used to distinguish between different components. The use of “including” or “comprising”, and the like, means that the presence of a component or item preceding the word encompasses the elements or items listed after the word and their equivalents, without excluding other elements or items. The terms such as “up/down”, “down/down”, “row/row direction” and “column/column direction” and the like indicate the orientation or positional relationship based on the orientation or positional relationship shown in the drawings for the sake of convenience only. The simplified description of the technical solution of the present disclosure is described, but does not indicate or imply that the pointed device or element must have a specific orientation, be constructed and operated in a specific orientation, and therefore should not be construed as limiting the present disclosure. For example, in some cases, embodiments involving “row direction” may be implemented in the “column direction” and so on, and vice versa. It is also within the scope of the patent right to rotate or mirror the structure described in this patent.

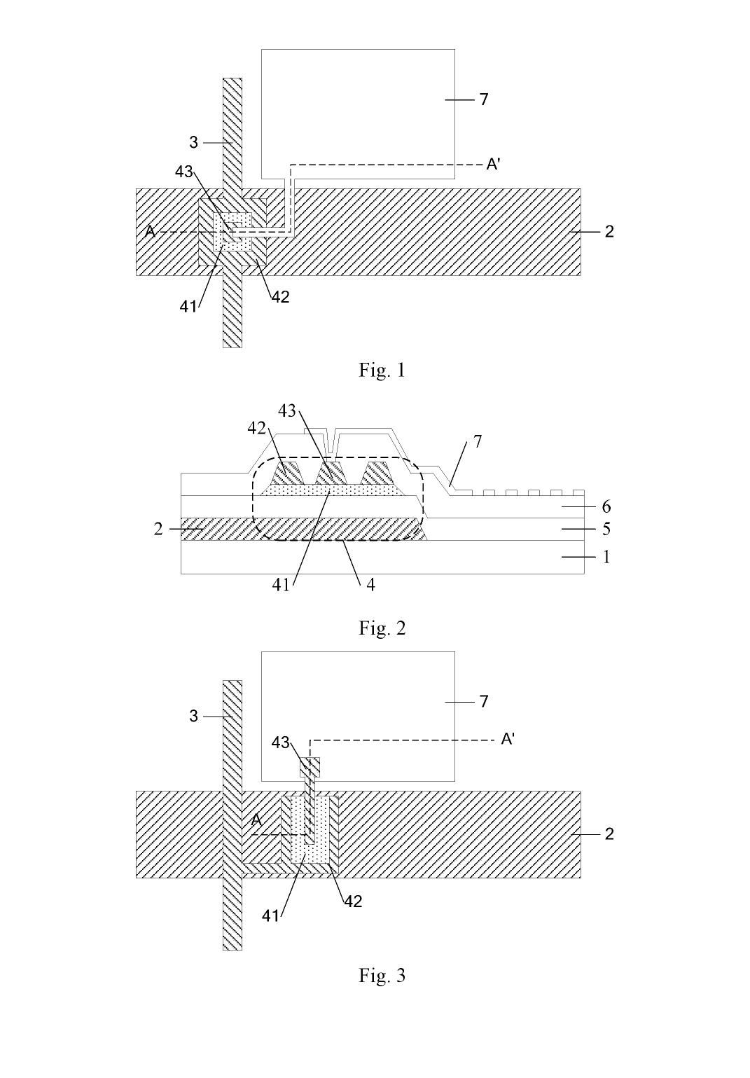

As shown in FIG. 1, an embodiment of the present disclosure provides an array substrate, including: a base substrate 1 (not shown in the figure), a gate line 2 and a data line 3 intersecting with each other over the base substrate 1, and a thin film transistor 4. The thin film transistor 4 includes: a gate electrode, an active layer 41 disposed on the side of the gate electrode away from the base substrate 1, and a source electrode 42 and a drain electrode 43 disposed on the side of the active layer 41 away from the base substrate 1. The gate electrode of the thin film transistor 4 is a part of the gate line 2. The source electrode 42 is a part of the data line 3, and at least partial area of the source electrode 42 is located within an area where orthogonal projections of the data line 3 and of the gate line 2 on the base substrate 1 overlap with each other.

It should be noted that, firstly, as shown in FIG. 2, the above array substrate also includes a gate insulating layer 5 covering the gate line 2, and the structure of the gate insulating layer 5 may be as in the related art, which is not limited in the embodiment of the present disclosure.

Secondly, the gate electrode of the thin film transistor 4 is a part of the main part of the gate line 2, rather than a pattern extending from the gate line 2. Similarly, the source electrode 42 is a part of the main part of the data line 3, rather than a pattern extending from the data line 3.

Thirdly, only one possible pattern of the source electrode 42 is illustrated in FIG. 1, and the embodiment of the present disclosure is not limited thereto. It will suffice as long as a part of the overlapping portion of the data line 3 and the gate line 2 may be taken as the source electrode 42. The pattern of the part of the data line 3 serving as the source electrode 42 may be flexibly adjusted according to the specific structural design of the thin film transistor 4.

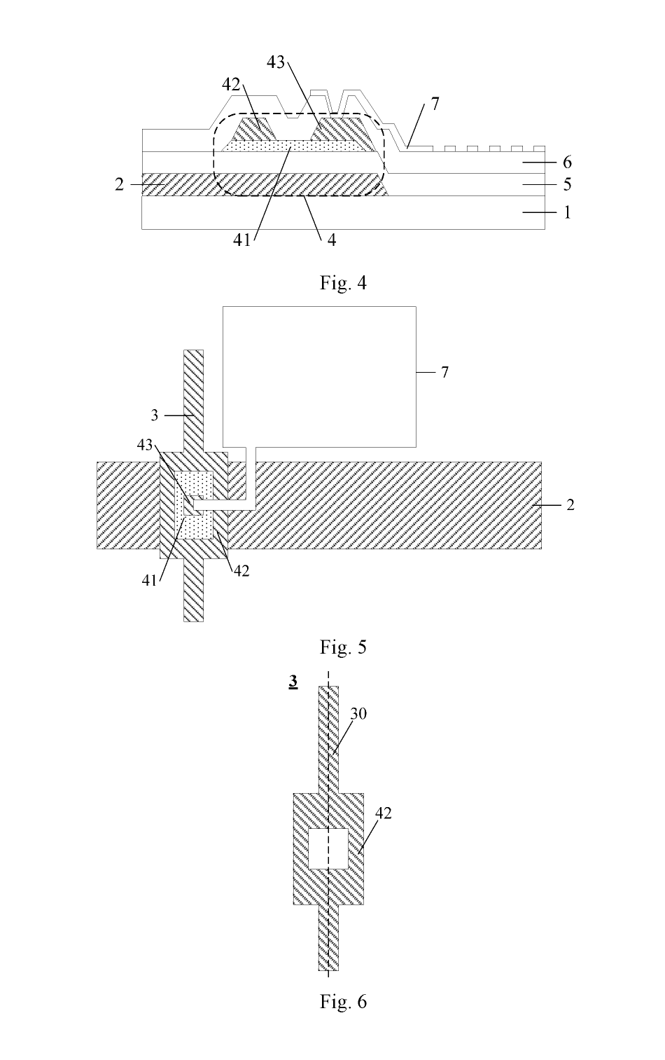

In an embodiment, as shown in FIG. 3 and FIG. 4, are respectively a top view and a cross sectional view of an array substrate in the related art. The data line 3 and the gate line 2 have an overlapping area on the base substrate 1. An independent source electrode 42 extending from the line 3, a drain electrode 43 opposite to the source electrode 42, and an active layer 41 located under the source electrode 42 and the drain electrode 43 are all disposed above the gate line 2. The area where the gate line 2 and the active layer 41 overlap with each other serves as a gate electrode, to form the thin film transistor 4. The drain electrode 43 is electrically connected to a pixel electrode 7 on a passivation layer 6 through a via hole on the passivation layer 6.

In the above array substrate in the related art, except for the area where the source electrode 42 is located, the data line 3, as the main part of a metal trace line, also overlaps with the gate line 2 below the data line 3, resulting in signal delay on the data line 3 and the gate line 2.

Referring to the foregoing FIG. 1 and FIG. 2, in the above-mentioned array substrate provided by the embodiment of the present disclosure, the overlapping portion of the data line 3 and the gate line 2 (or a part of the overlapping area) is taken as the source electrode 42 of the thin film transistor 4. That is, the area where the data line 3 and the gate line 2 overlap with each other is designed as the area where the thin film transistor 4 is located, thereby reducing the overlapping area of data line 3 and the gate line 2, as the main parts of the trace line for transmitting signals.

Accordingly, with the above array substrate provided by the embodiment of the present disclosure, by improving the structure of the thin film transistor of the related art, it can reduce the overlapping area between the data line and the gate line, as parts of the metal trace lines, and can effectively alleviate the problem of poor display such as Crosstalk and Flicker caused by applying to a display device an array substrate with overlapping data line and gate line. Moreover, since the overlapping area of the data line and the gate line serves as the area where the thin film transistor is located, it can allow flexibly adjusting the pattern of the overlapping area of the data line and the gate line (part or all of which serves as the area of the source electrode), to avoid the problem that the data line has to climb cross the gate line, effectively reducing the risk of data open of the data line.

Based on the above, the structure in the thin film transistor 4 may be as follows.

Referring to FIG. 2, in the case where the source electrode 42 is entirely located in an area where the orthogonal projections of the data line 3 and the gate line 2 on the base substrate 1 overlap, the orthogonal projection of the gate line 2 on the base substrate 1 completely covers the orthographic projection of the active layer 41 on the base substrate 1.

Correspondingly, the portion of the gate line 2 that overlaps with the active layer 41 serves as the gate electrode of the thin film transistor 4.

Alternatively, as shown in FIG. 5, in the case where a partial area of the source electrode 42 is located in an area where the orthogonal projections of the data line 3 and the gate line 2 on the base substrate 1 (not shown in the drawing) overlap, the orthogonal projection of the gate line 2 on the base substrate 1 partly covers the orthographic projection of the active layer 41 on the base substrate 1.

That is, since a partial area of the source electrode 42 is located on the overlapping area between the data line 3 and the gate line 2, and the remaining area of the source electrode 42 does not overlap with the gate line 2, a partial area of the active layer 41 below the source electrode 42 does not overlap with the gate line 2, and the part of the gate line 2 overlapping with the active layer 41 in the extending direction of the gate line 2 may serve as the gate electrode of the thin film transistor 4.

However, in the case where a partial area of the source electrode 42 is located on the overlapping area of the data line 3 and the gate line 2, and the remaining area does not overlap with the gate line 2, the projection on the base substrate 1 of the pattern of the active layer 41 which is located below the source electrode 42 and the drain electrode 43, may also be completely covered by the projection on the base substrate 1 of the part of the gate line 2 below which serves as the gate electrode. That is, the outline area of the pattern of the active layer 41 may also be slightly smaller than the outline area of the pattern of the source electrode 42, as long as it is ensured that in the above thin film transistor, the oppositely disposed source electrodes 42 and drain electrode 43 contact with the active layer 41 below repeatedly, realizing a stable electrical connection.

In an embodiment, as shown in FIGS. 1 and 5, the source electrode 42 has a loop shape and surrounds the drain electrode 43.

Here, the pattern of the source electrode 42 is a loop shape, and the drain electrode 43 is disposed in the loop, such that the area of the active layer 41 located in the opposite area of the source electrode 42 and the drain electrode 43 can be larger. That is, it can increase the channel area when the thin film transistor is turned on, and can improve the electrical performance of the thin film transistor 4.

The loop may be a rectangular loop or a circular loop to simplify the difficulty of patterning and etching the entire data line.

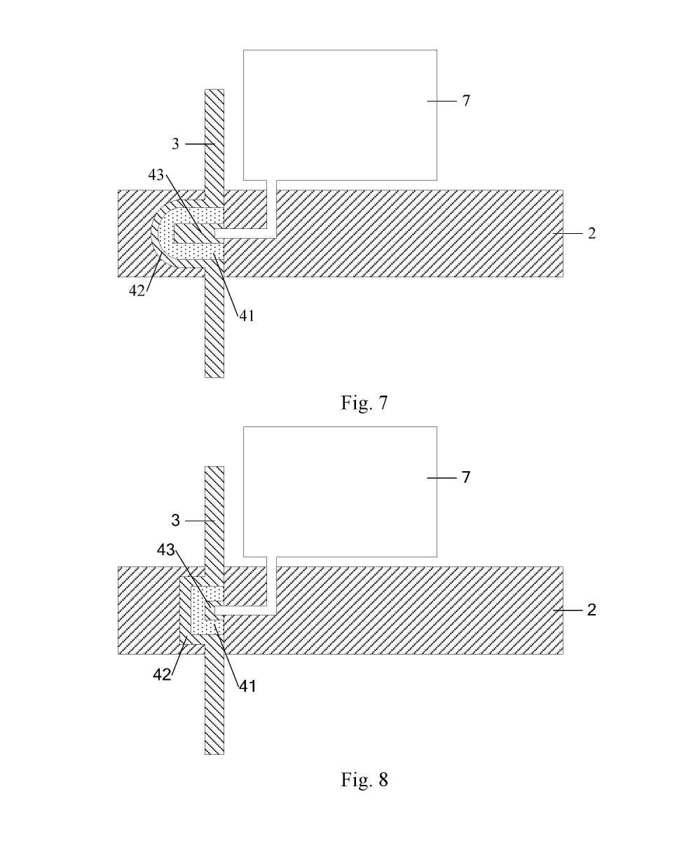

Moreover, in order to further reduce the difficulty of patterning the data line as a whole, the loop can be designed as having a symmetrical shape. As shown in FIG. 6, the data line 3 includes: a part serving as the source electrode 42 of the above thin film transistor and a part serving as a main part 30 of the trace line connecting to the source electrode 42, and the axis of symmetry of the loop (indicated by a dashed line in the drawing) coincides with the axis of symmetry of the main part 30 of the trace line in the extending direction.

Alternatively, the pattern of the source electrode 42 may also be a U shape as shown in FIG. 7 or a quasi-U shape as shown in FIG. 8. The opening direction of the U shape or the quasi-U shape is perpendicular to the extending direction of the data line 3. At least partial area of the drain electrode 43 is located in the opening area of the U shape or the quasi-U shape.

Here, the quasi-U shape refers to a pattern in which the bottom of the U shape is a straight line and both sides extend at right angles.

Based on the above, referring to FIG. 1, FIG. 2, FIG. 5, FIG. 7, and FIG. 8, the above array substrate may further include a passivation layer 6 (illustrated only in cross sectional view in FIG. 2) disposed on the gate line 2, the data line 3, and the thin film transistor 4, a pixel electrode 7 disposed on the passivation layer 6. The pixel electrode 7 is electrically connected to the drain electrode 43 below through a via hole on the passivation layer 6.

Here, when the pattern of the source electrode 42 is a U shape as shown in FIG. 7 or a quasi-U shape as shown in FIG. 8, since at least partial area of the drain electrode 43 is located in the opening area of the U shape or the quasi-U shape, that is, the pattern of the source electrode 42 does not completely enclosed by the drain electrode 43, the pixel electrode 7 may also be disposed on the gate insulating layer 5 and directly overlaps the drain electrode 43 to achieve electrical connection therebetween. The embodiment of the present disclosure is not limited to this, and existing technology in the art can be combined herein.

In an embodiment, the above array substrate may further include: a common electrode disposed between the pixel electrode and the base substrate. That is, the above array substrate is applicable to an ADS (Advanced-Super Dimensional Switching) type liquid crystal display device, and displays by driving a liquid crystal through a horizontal electric field formed between a common electrode and a pixel electrode.

Here, in order to reduce the overall thickness of the array substrate, the common electrode and the gate line may be disposed in the same layer.

An embodiment of the present disclosure further provides a method for manufacturing the above array substrate. The method includes the following steps. A gate line, a gate insulating layer, an active layer, a data line, and a drain electrode are formed sequentially over a base substrate. A part of the gate line serves as a gate electrode, an active layer is formed over the gate electrode, and a drain electrode is formed over the active layer. A part of the data line serves as a source electrode, and at least partial area of the source electrode is located in an area where orthogonal projections of the data line and of the gate line on the base substrate overlap with each other. The gate electrode, the active layer, the source electrode and the drain electrode constitute a thin film transistor (TFT).

The step of forming the data line and the drain electrode includes the following steps. A metal layer and a photoresist layer are formed sequentially over the base substrate formed with the gate line, the gate insulating layer and the active layer. A photoresist pattern is formed by exposing and developing the photoresist layer with a mask. The region of the metal layer covered by the photoresist pattern corresponds to patterns of the data line and the drain electrode to be formed. The region of the metal layer exposing to the photoresist pattern is etched, to form patterns of the data line and the drain electrode below the photoresist pattern. The photoresist pattern is removed by an ashing process to form the data line and the drain electrode.

Here, a pattern of the mask may be flexibly selected according to the design of the source pattern of the TFT to be formed, to obtain a pattern of the above data line a part of which in the extending direction of the data line serves as the source electrode of the TFT according to the embodiment of the present disclosure.

The material of the photoresist layer may be selected according to the existing technology, and the detailed principle will not be repeated here.

In an embodiment, before the step of sequentially forming a gate line, a gate insulating layer, an active layer, a data line and a drain electrode on a base substrate, the manufacturing method may also include a step of forming a common electrode on the base substrate.

In an embodiment, after the step of sequentially forming a gate line, a gate insulating layer, an active layer, a data line and a drain electrode on a base substrate, the manufacturing method may also include: a step of forming a passivation layer with a via hole over the base substrate, to expose the drain electrode below through the via hole; a step of forming a pixel electrode over the passivation layer, and electrically connecting the pixel electrode with the drain electrode through the via hole.

The manufacturing process of the array substrate with the above pixel electrode and the common electrode is as follows.

In step 1, a thin film deposition and patterning process are sequentially performed on the base substrate to form a common electrode.

The base substrate may be, for example, a transparent substrate such as a glass substrate.

The deposited thin film may be, for example, an ITO (Indium Tin Oxide) film to form a common electrode (ITO Com).

The patterning process refers to a process of applying a mask once, exposing, developing, and etching the thin film exposing to the photoresist on the surface of the thin film, to form a specific pattern and removing the photoresist.

In step 2, a thin film deposition and patterning process are sequentially performed on the base substrate after the above step 1 is completed, to form a gate line and a gate line trace disposed in the same layer as the gate line.

In step 3, a Gate Insulator (GI), an active layer (Active), and a SD metal layer are sequentially deposited on the base substrate after the above step 2 is completed, to form patterns of a data line and a drain electrode. Since the area on the data line overlapping with the gate line serves as the source electrode of the TFT, a new TFT structure may be formed while the data line and the drain electrode are formed.

The SD metal layer may, for example, a stacked structure of multiple layers of metal, such as Mo\Al\Mo.

Here, the pattern of the mask used in the patterning process of step 3 may be adjusted, to obtain the above data line and the drain electrode through the one patterning process.

Since the patterns of the data line and the drain electrode made of metal materials, the etching process in the above patterning process may be wet etching to obtain better etching selectivity and high production efficiency.

In step 4, a passivation layer is deposited on the base substrate after the above step 3 is completed, and a via hole is formed on the passivation layer through a patterning process to expose the drain electrode below.

In step 5, a thin film deposition and patterning process are sequentially performed on the base substrate after the above step 4 is completed, to form a pixel electrode. The pixel electrode is in contact with the drain electrode below through the via hole formed on the passivation layer in the above step 4, to achieve electrical connection between the two.

The deposited thin film may be, for example, an ITO thin film, to form an ITO pixel electrode.

Through the above steps, an array substrate applied in an ADS type liquid crystal display device may be formed.

Based on the above, an embodiment of the present disclosure further provides a display device including the above array substrate. The display device may be a liquid crystal display device, and may be a product or component having any display function such as a liquid crystal display, a liquid crystal television, a digital photo frame, a mobile phone, a tablet computer, a navigator, and the like.

The above description is only exemplary implementations of the present disclosure, but the protection scope of the present disclosure is not limited thereto. Any person skilled in the art can easily contemplate modification or replacement within the technical scope disclosed by the present disclosure. It should be covered by the protection scope of the present disclosure. Therefore, the protection scope of the present disclosure shall be subject to the protection scope of the claims.

1. An array substrate, comprising: a base substrate, a gate line and a data line intersecting with each other over the base substrate, and a thin film transistor; the thin film transistor comprising: a gate electrode, an active layer disposed on a side of the gate electrode away from the base substrate, and a source electrode and a drain electrode disposed on a side of the active layer away from the base substrate, wherein
the gate electrode is a part of the gate line;
the source electrode is a part of the data line, and at least partial area of the source electrode is located within an area where orthogonal projections of the data line and of the gate line on the base substrate overlap with each other.

2. The array substrate according to claim 1, wherein:
in the case where the source electrode is entirely located in an area where the orthogonal projections of the data line and of the gate line on the base substrate overlap with each other, the orthogonal projection of the gate line on the base substrate completely covers the orthographic projection of the active layer on the base substrate; and
in the case where a partial area of the source electrode is located in an area where the orthogonal projections of the data line and of the gate line on the base substrate overlap with each other, the orthogonal projection of the gate line on the base substrate partially covers the orthographic projection of the active layer on the base substrate.

3. The array substrate according to claim 1, wherein the pattern of the source electrode is a loop shape and surrounds the drain electrode.

4. The array substrate according to claim 3, wherein the loop shape is a rectangular loop or a circular loop.

5. The array substrate according to claim 3, wherein the data line comprises: a first part serving as the source electrode and a second part serving as a main part of a trace line connecting to the source electrode, and an axis of symmetry of the loop coincides with an axis of symmetry of the main part of the trace line in the extending direction.

6. The array substrate according to claim 1, wherein:
a pattern of the source electrode is a U shape or a quasi-U shape, and an opening direction of the U shape or the quasi-U shape is perpendicular to an extending direction of the data line; and
at least partial area of the drain electrode is located in an opening area of the U shape or the quasi-U shape.

7. The array substrate according to claim 1, further comprising: a passivation layer disposed on the gate line, the data line, and the thin film transistor, and a pixel electrode disposed on the passivation layer; and wherein the pixel electrode is electrically connected to the drain electrode through a via hole on the passivation layer.

8. The array substrate according to claim 7, further comprising: a common electrode disposed between the pixel electrode and the base substrate.

9. The array substrate according to claim 8, wherein the common electrode is disposed in the same layer as the gate line.

10. A display device comprising the array substrate according to claim 1.

11. A manufacturing method for an array substrate, comprising:
sequentially forming a gate line, a gate insulating layer, an active layer, a data line, and a drain electrode over a base substrate;
wherein a part of the gate line serves as a gate electrode, an active layer is formed over the gate electrode, and a drain electrode is formed over the active layer;
a part of the data line serves as a source electrode, and at least partial area of the source electrode is located in an area where orthogonal projections of the data line and of the gate line on the base substrate overlap with each other; and
the gate electrode, the active layer, the source electrode and the drain electrode constitute a thin film transistor.

12. The manufacturing method according to claim 11, wherein the step of forming the data line and the drain electrode comprises:
sequentially forming a metal layer and a photoresist layer over the base substrate formed with the gate line, the gate insulating layer and the active layer;
forming a photoresist pattern by exposing and developing the photoresist layer with a mask, with the region of the metal layer covered by the photoresist pattern corresponding to patterns of the data line and the drain electrode to be formed; and
etching the region of the metal layer exposing to the photoresist pattern, to form patterns of the data line and the drain electrode below the photoresist pattern; and
removing the photoresist pattern to form the data line and the drain electrode.

13. The manufacturing method according to claim 11, wherein before the step of sequentially forming a gate line, a gate insulating layer, an active layer, a data line and a drain electrode on a base substrate, the manufacturing method further comprises forming a common electrode on the base substrate.

14. The manufacturing method according to claim 11, wherein after the step of sequentially forming a gate line, a gate insulating layer, an active layer, a data line and a drain electrode on a base substrate, the manufacturing method further comprises:
forming a passivation layer with a via hole over the base substrate, to expose the drain electrode below through the via hole; and
forming a pixel electrode over the passivation layer, and electrically connecting the pixel electrode with the drain electrode through the via hole.
